(19) United States
(12) Patent Application Publication
(10) Pub. No.: US 2026/0223676 A1
(43) Pub. Date: Jul. 30, 2026

(54) BACKFIN CHIP FOR DIRECT COOLING OF A MICRO-CHIP

(71) Applicant: OpenAI OpCo, LLC, San Francisco, CA (US)

(72) Inventors: Teck Gyu Kang, Saratoga, CA (US); Reza Haji Aghaee Khiabani, San Mateo, CA (US)

(73) Assignee: OpenAI OpCo, LLC, San Francisco, CA (US)

(21) Appl. No.: 19/037,918

(22) Filed: Jan. 27, 2025

(51) Int. Cl. H01L 23/473; H01L 21/56; H01L 23/00; H01L 23/433; H01L 25/00; H01L 25/065; H10D 80/30

(52) U.S. Cl. CPC H10W 40/47; H10W 40/77; H10W 42/00; H10W 74/016; H10W 90/00; H10D 80/30; H10W 72/07236; H10W 90/724

(57) ABSTRACT

The present technology relates to a packaged microchip that includes a substrate (e.g., a silicon interposer) to which dies (e.g., circuits fabricated on silicon) and a high thermal conductivity protection layer (e.g., CVD diamond) are provided directly on the thermal-interface surface of the dies. The protection layer is impervious to a cooling liquid to protect from the cooling liquid leaking into the dies. A lid is fixed to the substrate (e.g., via a stiffener member and a PCB) to form with the protection layer a space/channel through which the cooling liquid flows to cool the packaged microchip.

### BACKGROUND

Thermal management is a foundational aspect of high-performance computing (HPC) that affects system efficiency, stability, and scalability. In an era where chips are getting faster and denser, effectively managing heat becomes increasingly important for ensuring that HPC systems can operate at their maximum potential. Effective thermal solutions enable higher performance, longer component lifespans, reduced energy consumption, and the ability to handle ever-increasing workloads in a sustainable manner.

Thermal management is important for high-performance computing (HPC) because of the large amount of heat generated by the processors, accelerators (e.g., graphics processing units (GPUs)), and other components that drive these systems. As computational power increases, so too does the need for effective heat dissipation. Inefficient thermal management can result in performance degradation, hardware failure, reduced system reliability, and shorter lifespans for the components. In HPC environments, where systems are often running continuously at full load, thermal management is increasingly important for maintaining performance and ensuring system longevity.

Failure to properly remove heat can cause various problems. For example, overheating occurs when the temperature of a component exceeds its designed operational limits, leading to instability, malfunction, or permanent damage. Thermal throttling is a protective mechanism where a processor or graphics processing unit (GPU) reduces its clock speed and performance to lower the temperature when it gets too hot. Although thermal throttling can prevent hardware damage, it also degrades the system's overall performance.

Prolonged exposure to high temperatures accelerates the degradation of semiconductor materials, reducing their lifespan. As microchips age due to high temperatures, they may become prone to faults like increased leakage current, transistor breakdowns, and other failures.

High-performance chips, especially multi-core CPUs and GPUs, can experience thermal cycling arising from repeated heating and cooling of components. This can lead to physical stress and eventual failure of the components, especially in solder joints and circuit traces. Good thermal management reduces these stresses by maintaining a more stable temperature profile. High temperatures can also damage other sensitive components such as memory, voltage regulators, and power delivery systems, leading to higher failure rates and reduced reliability.

As HPC systems scale to handle more computational tasks, the heat density within processors and GPUs increases. Many modern chips contain billions of transistors packed into ever-smaller areas. This leads to very high heat generation in small, concentrated regions.

Managing this high heat density depends on developing improved thermal transfer and cooling technologies. Current technologies include, for example, placing a thermal interface material (TIM) on the dies and transferring heat from the microchip through the TIM to a cold plate which either dissipates the heat via a heat sink to the environment or transfers the heat to a cooling liquid. This approach to heat transfer is limited by the thermal resistance presented by each layer through which the heat propagates.

It is with these observations in mind, among others, that various aspects of the present disclosure were conceived and developed.

### BRIEF DESCRIPTION OF THE SEVERAL VIEWS OF THE DRAWINGS

Details of one or more aspects of the subject matter described in this disclosure are set forth in the accompanying drawings and the description below. However, the accompanying drawings illustrate only some typical aspects of this disclosure and are therefore not to be considered limiting of its scope. Other features, aspects, and advantages will become apparent from the description, the drawings, and the claims.

FIG. 1A illustrates a first example of a packaged microchip, in accordance with some embodiments.

FIG. 1B illustrates a second example of a packaged microchip, in accordance with some embodiments.

FIG. 1C illustrates a third example of a packaged microchip, in accordance with some embodiments.

FIG. 1D illustrates a fourth example of a packaged microchip, in accordance with some embodiments.

FIGS. 2A-F illustrates respective states of assembly for the packaged microchip having a cooling-liquid channel and protection layer close to the dies in accordance with some embodiments.

FIG. 3 illustrates a method for assembling a packaged microchip, in accordance with some embodiments.

### DETAILED DESCRIPTION

Various embodiments of the disclosure are discussed in detail below. While specific implementations are discussed, it should be understood that this is done for illustration purposes only. A person skilled in the relevant art will recognize that other components and configurations may be used without parting from the spirit and scope of the disclosure.

In some aspects, the techniques described herein relate to a packaged microchip, including: a substrate; one or more dies including a circuit fabricated on a semiconductor, a die of the one or more dies having a substrate surface and a thermal-interface surface on an opposite surface of the die from the substrate surface, the die being fixed to the substrate by the substrate surface of the die; a protection layer provided directly on the thermal-interface surface, the protection layer being impervious to a cooling liquid; and a lid fixed to the substrate and forming a space between the protection layer and the lid that is configured to allow the cooling liquid to flow thereby cooling the packaged microchip.

In some aspects, the techniques described herein relate to a method for providing a packaged microchip, the method including: fixing one or more dies to a substrate, a die of the one or more dies including a circuit fabricated on a semiconductor, and the one or more dies having a substrate surface, which faces the substrate, and a thermal-interface surface on an opposite surface of the die from the substrate surface; forming a protection layer provided directly on the thermal-interface surface of the one or more dies; fixing a lid to the substrate to form a space between the protection layer and the lid through which a cooling liquid flows to cool the packaged microchip.

Compared to lidless and lidded packaging designs for packaging dies, the systems and methods disclosed herein provide improved heat removal by providing heat transfer to a cooling liquid close to the dies, removing layers of thermal resistance that are present in previous heat-transfer approaches. Compared to direct liquid cooling of dies, the systems and methods disclosed herein provide improvements with respect to corrosion resistance and reduced likelihood of the cooling fluid leaking into the circuits of the dies and causing failures. The systems and methods disclosed herein provide a protection layer (e.g., a diamond layer) directly on the surface of the dies. The protection layer is impervious to liquids such that a cooling liquid flowing through a space/channel next to the protection layer does not present a risk of leaking into the dies. Further, the protection layer can be a corrosion-resistant material such as diamond thereby preventing corrosion in the space/channel through which the cooling liquid flows. When the protection layer has a high thermal conductivity and is relatively thin, such as a thin layer of diamond (e.g., a layer thickness of less than 500 microns, less than 100 microns, or less than 50 microns), the protection layer presents little thermal resistance to heat removal via the cooling liquid.

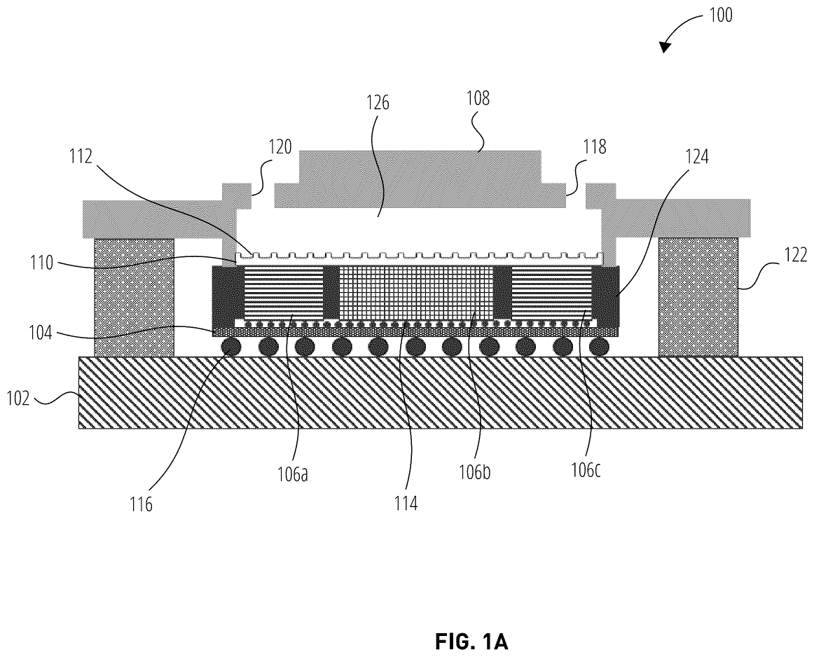

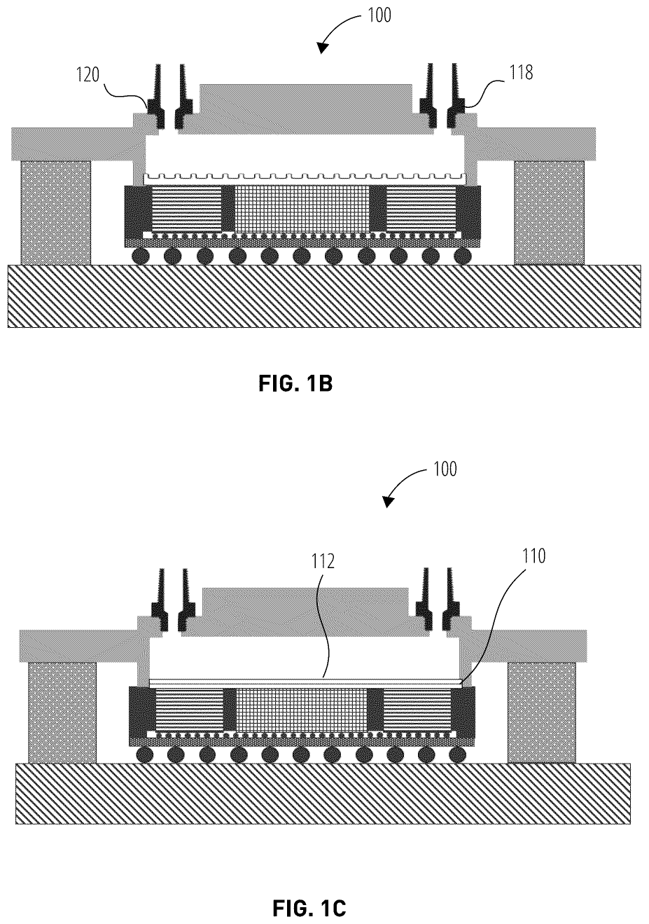

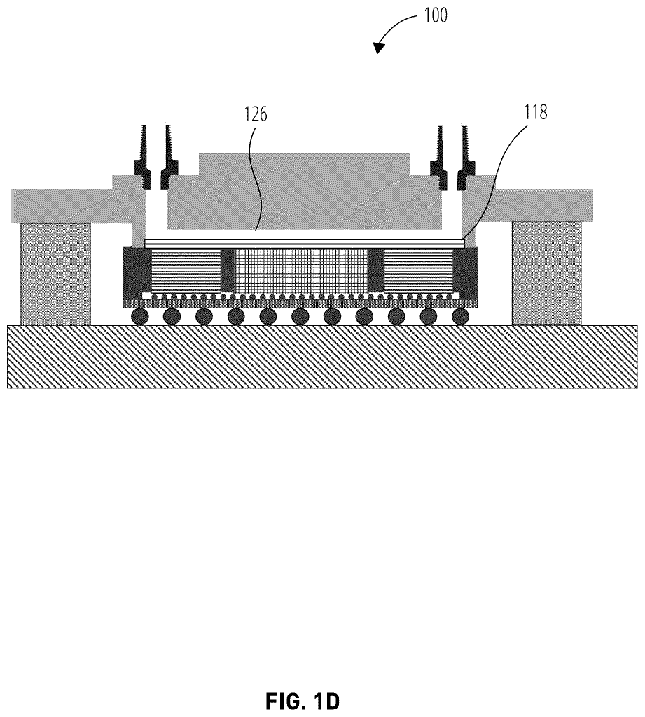

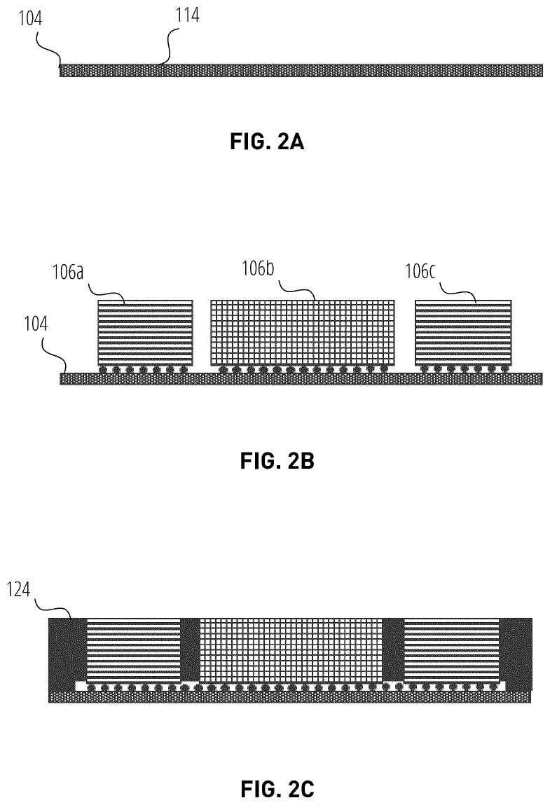

FIG. 1A illustrates an example of a packaged microchip 100 having channel 126 formed between lid 108 and protection layer 110 through which a cooling liquid can flow to cool packaged microchip 100. Packaged microchip 100 can include dies 106 (e.g., die 106a, die 106b, and die 106c) mounted on a substrate (e.g., interposer 104) via microbumps 114. Packaged microchip 100 can include lid 108, which is bonded to printed circuit board 102 via stiffeners 122. Printed circuit board 102 can be connected to interposer 104 via microbumps 116. A cooling liquid flows into channel 126 through inlet port 118 and out through outlet port 120.

Protection layer 110 can include heat-transfer structure 112 on its top surface, which faces away from dies 106. For example, heat-transfer structure 112 can be fins that increase a surface area for transferring heat to a cooling liquid such as water or another liquid. Additionally or alternatively, heat-transfer structure 112 can include microstructure or nanostructure that provides improved heat transfer. For simplicity, the term “microstructure” is used herein to refer to the structure on the top surface of lid 108 regardless of whether this structure is on a millimeter, micrometer, and/or nanometer scale.

Protection layer 110 provides various benefits. For example, in the absence of protection layer 110, the cooling liquid may cause corrosion of the materials in molding 124 and/or dies 106. Further, if, over time, cracks or voids are formed between molding 124 and dies 106, the cooling liquid may leak into these cracks or voids and into the circuits of dies 106 causing one or more of dies 106 to fail. Thus, protection layer 110 protects dies 106 from the cooling liquid.

Additionally, protection layer 110 can present minimal thermal resistance between the cooling liquid and dies 106. For example, protection layer 110 can be thin (e.g., between 10 microns and 500 microns) and can be made of a high-conductivity material such as chemical vapor deposition (CVD) diamond, resulting in high-efficiency heat transfer from dies 106 to the cooling liquid.

According to certain non-limiting examples, dies 106 can use flip-chip technology to mount dies 106 to interposer 104. In flip-chip technology, the microchip (or die) is mounted upside down (flipped) onto the substrate. Instead of traditional wire bonding, electrical connections are made through small bumps of solder or conductive material on the chip's surface. Dies 106 can be a silicon chip on which an integrated circuit has been fabricated, and the silicon chip can have metallic pads on its surface where solder bumps are applied. Interposer 104 can provide mechanical support and electrical connections. Further, interposer 104 can have multiple metallization layers that consist of copper or gold and provide electrical pathways for signals and power.

Microbumps 114 can be created on pads of dies 106. These bumps serve as the connection points to the substrate. Examples of materials for these bumps include lead-tin solder or newer, lead-free alternatives. Microbumps 114 can be a ball grid array (BGA). Similarly, microbumps 116 can provide electrical connections between printed circuit board 102 and interposer 104.

Mounting a chip to a printed circuit board (PCB) can provide proper electrical connections and mechanical stability. The PCB can have pads and traces to accommodate the interposer, wherein the PCB is designed with pads arranged in a grid pattern corresponding to the solder balls on the ball grid array (BGA) of the interposer. Each pad is sized and positioned to match the ball dimensions for effective soldering. Solder balls are pre-attached to the BGA interposer during manufacturing. These balls can be, e.g., lead-free solder or lead-based solder, depending on the application. A pick-and-place machine picks up the BGA interposer and positions it over the PCB. Precise alignment ensures that each solder ball sits directly over its corresponding pad on the PCB.

After placement, the PCB assembly can be placed in a reflow oven. The reflow process can include preheating, soaking, and reflow of the PCB assembly. During preheating, the assembly is gradually heated to remove moisture and prepare the solder for melting. During soaking, the temperature is held steady for a short duration to allow even heating and activation of the flux within the solder balls. During reflow, the temperature is raised to the solder melting point (e.g., about 217° C. for leaded solder) where the solder balls melt, forming a liquid solder connection between the chip and the PCB pads. Next, the assembly is cooled to solidify the solder joints. Gradually cooling helps to avoid thermal shock and to ensure reliable connections.

FIG. 1B illustrates an example in which threaded ports are provided for inlet port 118 and outlet port 120. These threaded ports enable tubing with threaded ends to be attached to lid 108. The tubing can connect a cooling system to lid 108 and to circulate the cooling liquid through channel 126 to cool packaged microchip 100. In this example, heat-transfer structure 112 is arranged perpendicular to the flow direction of the cooling liquid, which can result in the turbulant flow and mixing of the cooling liquid.

In FIG. 1C, packaged microchip 100 is the same as in FIG. 1A, except heat-transfer structure 112 is arranged parallel to the flow direction of the cooling liquid, which can preserve the laminar flow of the cooling liquid.

FIG. 1D illustrates another example of packaged microchip 100. In this example, the vertical dimension of channel 126 is decreased resulting in the cooling liquid flowing closer to protection layer 110. When the vertical dimension of channel 126 is large, parts of the cooling liquid flowing near the top of channel 126 may experience little heat transfer. According to certain non-limiting examples, channel 126 can form grooves or channels through which the cooling liquid flows.

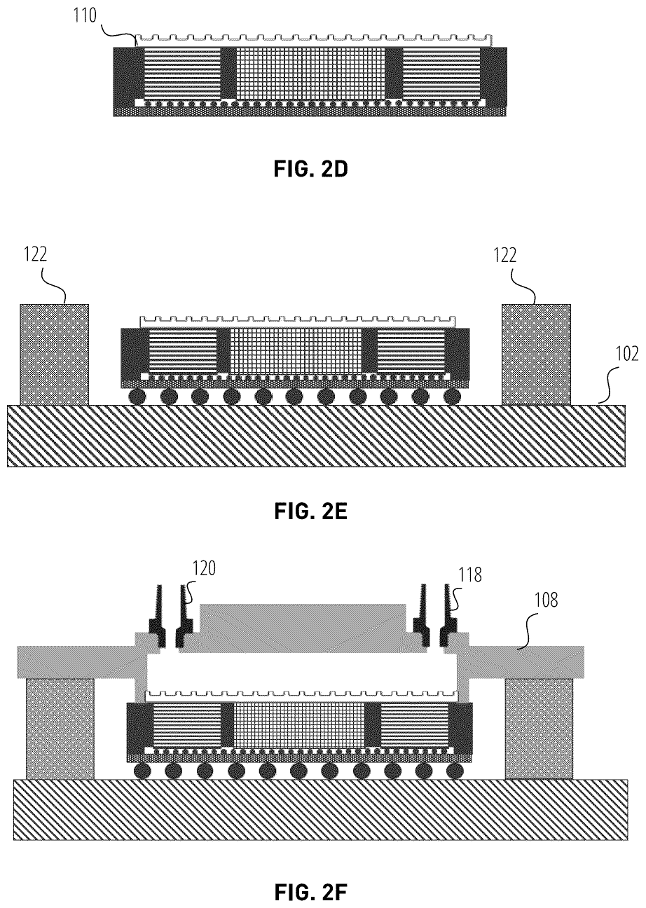

FIGS. 2A-2F illustrate packaged microchip 100 at various points during assembly. FIG. 2A shows interposer 104 before any other components of packaged microchip 100 have been added.

FIG. 2B shows the combination of interposer 104 and dies 106, after mounting dies 106 to interposer 104. According to certain non-limiting examples, the assembly of dies 106 on interposer 104 can be performed using flip-chip technology. Flip-chip technology is a packaging technique used to mount the chips directly onto substrates, allowing for high-performance connections.

In flip-chip technology, the microchip (or die) is mounted upside down (flipped) onto the substrate, which contrasts with wire-bonding electrical connections. For example, the die can be a silicon chip on which an integrated circuit has been fabricated. The die has metallic pads on its surface where solder bumps (e.g., microbumps 114) are applied. The interposer can be a silicon interposer. Alternatively, the interposer can be a material like a glass-reinforced epoxy laminate material (e.g., FR4), ceramic, or other high-performance materials, for example. The interposer provides mechanical support and electrical connections. Further, the interposer can include metallization layers, which can be, e.g., copper or gold, providing pathways to the die for signals and power.

Microbumps 114 can be solder bumps that are created on the pads of the die, providing connection points to the interposer. To mount the die on the interposer, the die can aligned over the interposer, ensuring that the solder bumps are correctly positioned over the corresponding pads on the interposer. Heat is then applied to melt the solder bumps, allowing them to flow and create strong electrical and mechanical connections between the die and the interposer. The assembly is then cooled, solidifying the solder and forming robust connections.

FIG. 2C shows packaged microchip 100 after a molding 124 has been provided around the sides of dies 106.

FIG. 2D shows packaged microchip 100 after providing protection layer 110 on a thermal-interface surface of dies 106. protection layer 110 can be a metal or a crystalline material. For example, diamond is an advantageous material for protection layer 110. Diamond has a high thermal conductivity (e.g., 2200 W/m·K), a low permeability to water and other liquids, and is generally corrosion resistant to most liquids. Other materials that may be used for protection layer 110 can include, for example, silver (430 W/m·K), gold (315 W/m·K), or copper (400 W/m·K). For example, the material of protection layer 110 can be selected to have a thermal conductivity greater than 300 W/mK and is corrosion-resistant to the cooling liquid.

According to certain non-limiting examples, protection layer 110 is diamond that is grown directly on a heat-dissipating side of the one or more dies using chemical vapor deposition.

Heat-transfer structure 112 can be fabricated, for example, by patterning photoresist on protection layer 110 and etching using an etching technique that corresponds to the material chosen for protection layer 110. Heat-transfer structure 112 can increase the thermal transfer from the protection layer to the cooling liquid by increasing a surface area over which the protection layer contacts the cooling liquid. Heat-transfer structure 112 can include fins that have a long dimension that runs along a direction of flow of the cooling liquid. Heat-transfer structure 112 can provide one or more channels arranged such that the cooling liquid passes through the one or more channels.

According to certain non-limiting examples, protection layer 110 is provided directly on the thermal-interface surface by depositing or growing the protection layer on the thermal-interface surface using chemical vapor deposition, physical vapor deposition, pulsed laser deposition, molecular beam epitaxy, sputter deposition, epitaxial growth, or electron beam deposition.

According to certain non-limiting examples, protection layer 110 has a thermal conductivity greater than 300 W/mK and is corrosion-resistant to the cooling liquid.

According to certain non-limiting examples, protection layer 110 can include heat-transfer structure 112 that enhance heat transfer, e.g., by increasing the surface area for heat transfer or by providing channels through which a liquid such as water with high thermal conductivity and high specific heat can flow. For example, heat-transfer structure 112 can incorporate fins or pillars, which are extended surfaces that increase the surface area available for heat transfer. Fins (and pillars) can enhance heat dissipation, especially in air-cooled applications. The fins can be made from the same material as the plate or different materials for optimized performance. Further, heat-transfer structure 112 can include internal channels through which coolant flows. These channels can be designed in various configurations (straight, serpentine, etc.) to maximize fluid contact with the cold plate surface, thereby enhancing liquid cooling efficiency by increasing the heat transfer area and improving fluid flow dynamics.

FIG. 2E shows packaged microchip 100 after interposer 104 and stiffener 122 have been connected to printed circuit board 102. For example, solder reflow with microbumps 116 can be used to connect interposer 104 to printed circuit board 102. As discussed above with reference to FIG. 1A, Microbumps 116 can be solder balls that are attached to interposer 104. Microbumps 116 can be aligned to metal pads on printed circuit board 102, and the assembly of interposer 104 and printed circuit board 102 can be heated to reflow the solder.

Further, an adhesive can be used to attach stiffener 122 to printed circuit board 102. The adhesive can be applied to a portion of printed circuit board 102 surrounding interposer 104 and dies 106. The adhesive can be selected to have a high strength. For example, the adhesive can be selected to have a high enough strength to withstand anticipated stresses/forces applied between lid 108 and printed circuit board 102.

FIG. 2F shows packaged microchip 100 after lid 108 has been connected to stiffeners 122. For example, lid 108 can be connected to stiffeners 122 by the adhesive. Here, the adhesive fixes stiffener 122 to lid 108.

According to certain non-limiting examples, lid 108 can also function as a cold plate that transfers some heat to the surrounding environment. For example, lid 108 can be a monolithic mechanical member fabricated out of a metal, such as copper, aluminum, nickel-plated copper, or stainless steel. Copper can have a thermal conductivity of about 400 W/m·K, making it highly effective for heat transfer. Aluminum is lighter than copper and can have a thermal conductivity of about 235 W/m·K, making it effective for heat transfer but not as effective as copper. Nickel-plated copper can be used to avoid the corrosion and oxidation of copper. Properties: Nickel-plated copper combines copper's high thermal conductivity with nickel's corrosion resistance, which is beneficial for liquid cooling applications. Stainless steel has a lower thermal conductivity than copper and aluminum but can provide excellent corrosion resistance.

The combination of stiffener 122 and lid 108 can increase the rigidity of packaged microchip 100 and mitigating warping of dies 106 thereby reducing the likelihood of cracks forming in dies 106, moldings 124, or between them.

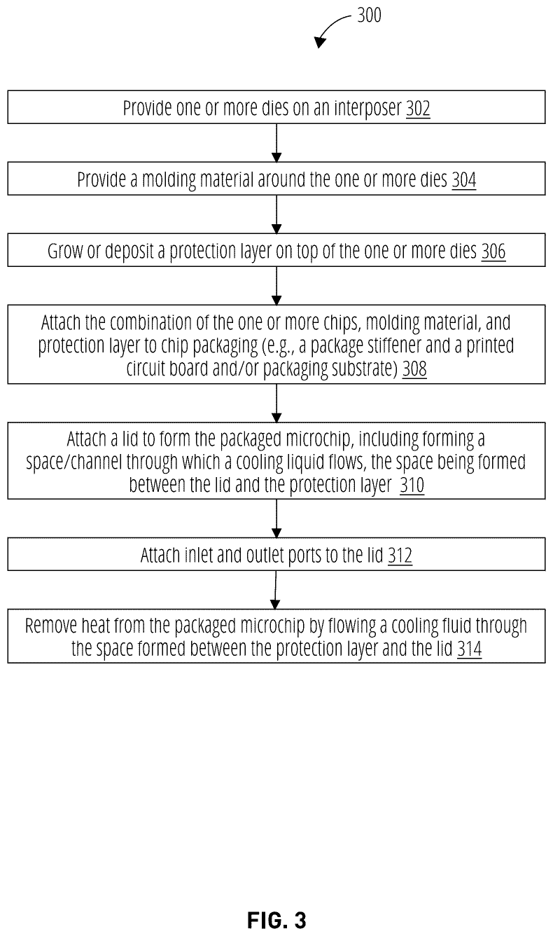

FIG. 3 illustrates an example method 300 for assembling a packaged microchip 100 with channel 126 formed in a space between lid 108 and protection layer 110, where dies 106 are cooled by flowing a cooling liquid through channel 126. Although the example method 300 depicts a particular sequence of operations, the sequence may be altered without departing from the scope of the present disclosure. For example, some of the operations depicted may be performed in parallel or in a different sequence that does not materially affect the function of method 300. In other examples, different components of an example device or system that implements method 300 may perform functions at substantially the same time or in a specific sequence.

According to some examples, the method includes providing one or more dies on an interposer at step 302. For example, dies 106 can be provided on interposer 104. According to certain non-limiting examples, dies 106 can be fabricated on silicon using flip-chip technology, and solder reflow is used to connect dies 106 to interposer 104, as discussed above.

According to some examples, the method includes providing a molding material around the one or more dies at step 304. For example, molding 124 can be provided around dies 106.

According to some examples, the method includes growing or depositing a protection layer on top of the one or more dies at step 306. For example, protection layer 110 can be grown on a combination of dies 106 and molding 124. According to certain non-limiting examples, protection layer 110 is diamond that is grown using chemical vapor deposition directly on a heat-dissipating side of the one or more dies. Protection layer 110 can be provided on dies 106 as shown in FIG. 2D and discussed with reference thereto.

According to some examples, step 308 of the method includes attaching the combination of the one or more dies, molding material, and protection layer to chip packaging (e.g., a package stiffener and a printed circuit board). For example, printed circuit board 102 and stiffeners 122 can be attached as shown in FIG. 2E and discussed with reference thereto.

According to some examples, step 310 of the method includes attaching a lid to form the packaged microchip, including forming a space/channel through which a cooling liquid flows, the space being formed between the lid and the protection layer. For example, lid 108 can be attached to stiffeners 122 to form packaged microchip 100 as shown in FIG. 2F and discussed with reference thereto.

According to some examples, the method includes attaching inlet and outlet ports to the lid at step 312.

According to some examples, the method includes removing heat from the packaged microchip by flowing a cooling fluid through the space formed between the protection layer and the lid at step 314.

For clarity of explanation, in some instances, the present technology may be presented as including individual functional blocks including functional blocks comprising devices, device components, steps or routines in a method embodied in software, or combinations of hardware and software.

Any of the steps, operations, functions, or processes described herein may be performed or implemented by a combination of hardware and software services or services, alone or in combination with other devices. In some embodiments, a service can be software that resides in memory of a client device and/or one or more servers of a content management system and perform one or more functions when a processor executes the software associated with the service. In some embodiments, a service is a program or a collection of programs that carry out a specific function. In some embodiments, a service can be considered a server. The memory can be a non-transitory computer-readable medium.

In some embodiments, the computer-readable storage devices, mediums, and memories can include a cable or wireless signal containing a bit stream and the like. However, when mentioned, non-transitory computer-readable storage media expressly exclude media such as energy, carrier signals, electromagnetic waves, and signals per se.

Methods according to the above-described examples can be implemented using computer-executable instructions that are stored or otherwise available from computer-readable media. Such instructions can comprise, For example, instructions and data which cause or otherwise configure a general purpose computer, special purpose computer, or special purpose processing device to perform a certain function or group of functions. Portions of computer resources used can be accessible over a network. The executable computer instructions may be, For example, binaries, intermediate format instructions such as assembly language, firmware, or source code. Examples of computer-readable media that may be used to store instructions, information used, and/or information created during methods according to described examples include magnetic or optical disks, solid-state memory devices, flash memory, USB devices provided with non-volatile memory, networked storage devices, and so on.

Devices implementing methods according to these disclosures can comprise hardware, firmware and/or software, and can take any of a variety of form factors. Typical examples of such form factors include servers, laptops, smartphones, small form factor personal computers, personal digital assistants, and so on. The functionality described herein also can be embodied in peripherals or add-in cards. Such functionality can also be implemented on a circuit board among different chips or different processes executing in a single device, by way of further example.

The instructions, media for conveying such instructions, computing resources for executing them, and other structures for supporting such computing resources are means for providing the functions described in these disclosures.

### Aspects

The present technology includes computer-readable storage mediums for storing instructions, and systems for executing any one of the methods embodied in the instructions addressed in the aspects of the present technology presented below:

Aspect 1. A packaged microchip, comprising: a substrate; one or more dies comprising a circuit fabricated on a semiconductor, a die of the one or more dies having a substrate surface and a thermal-interface surface on an opposite surface of the die from the substrate surface, the die being fixed to the substrate by the substrate surface of the die; a protection layer provided directly on the thermal-interface surface, the protection layer being impervious to a cooling liquid; and a lid fixed to the substrate and forming a space between the protection layer and the lid that is configured to allow the cooling liquid to flow thereby cooling the packaged microchip.

Aspect 2. The packaged microchip of aspect 1, wherein the protection layer has a thermal conductivity greater than 300 W/mK and is corrosion-resistant to the cooling liquid.

Aspect 3. The packaged microchip of aspect 1 or aspect, wherein the protection layer is diamond.

Aspect 4. The packaged microchip of aspect 3, the diamond is grown directly on a heat-dissipating side of the one or more dies using chemical vapor deposition.

Aspect 5. The packaged microchip of any of aspects 1-4, wherein the protection layer comprises a metal or a crystalline material.

Aspect 6. The packaged microchip of any of aspects 1-5, wherein: in addition to the substrate surface and the thermal-interface surface, the one or more dies have side surfaces, and a molding is provided around the side surfaces of the one or more dies, the substrate is a silicon interposer that is fixed to the one or more dies via solder reflow of microbumps, the silicon interposer is connected to a printed circuit board via another solder reflow of other microbumps, the lid is either directly fixed to the printed circuit board or indirectly fixed to the printed circuit board via one or more stiffener members, and the lid comprises an inlet port through which the cooling liquid flows into the space and an outlet port through which the cooling liquid flows out of the space.

Aspect 7. The packaged microchip of any of aspects 1-6, wherein the space between the protection layer and the lid provides at least a grade 2 hermetic seal protecting the one or more dies from the cooling liquid in the space.

Aspect 8. The packaged microchip of any of aspects 1-7, wherein the protection layer has a die surface and a heat-dissipating surface, the die surface being a surface that faces the one or more dies, and the heat-dissipating surface having a structure.

Aspect 9. The packaged microchip of aspect 8, wherein the structure has been formed by etching the protection layer.

Aspect 10. The packaged microchip of aspect 8 or aspect 9, wherein the structure increases thermal transfer from the protection layer to the cooling liquid by increasing a surface area over which the protection layer contacts the cooling liquid.

Aspect 11. The packaged microchip of any of aspects 8-10, wherein the structure on the protection layer includes a microstructure or a nanostructure.

Aspect 12. The packaged microchip of any of aspects 8-11, wherein the structure on the protection layer includes fins that have a long dimension that runs along a direction of flow of the cooling liquid.

Aspect 13. The packaged microchip of any of aspects 8-12, wherein the structure on the protection layer provide one or more channels arranged such that the cooling liquid passes through the one or more channels.

Aspect 14. The packaged microchip of any of aspects 1-13, wherein, in addition to being impervious to the cooling liquid, the protection layer is corrosion resistant to the cooling liquid thereby protecting the one or more dies from the cooling liquid leaking from the space to the one or more dies.

Aspect 15. The packaged microchip of any of aspects 1-14, wherein the protection layer is provided directly on the thermal-interface surface by depositing or growing the protection layer on the thermal-interface surface using chemical vapor deposition, physical vapor deposition, pulsed laser deposition, molecular beam epitaxy, sputter deposition, epitaxial growth, or electron beam deposition.

Aspect 16. The packaged microchip of any of aspects 1-15, further comprising: an inlet port through which the cooling liquid enters the space; and an outlet port through which the cooling liquid exits the space, wherein the protection layer has a die surface and a heat-dissipating surface, the die surface being a surface that faces the one or more dies, and the heat-dissipating surface having a structure, and the structure is arranged to provide laminar flow of the cooling liquid when the cooling liquid is flowing from the inlet port to the outlet port.

Aspect 17. The packaged microchip of any of aspects 1-16, further comprising: an inlet port through which the cooling liquid enters the space; and an outlet port through which the cooling liquid exits the space, wherein the protection layer has a die surface and a heat-dissipating surface, the die surface being a surface that faces the one or more dies, and the heat-dissipating surface having a structure, and the structure is arranged to provide turbulant flow of the cooling liquid when the cooling liquid is flowing from the port to the outlet port.

Aspect 18. A method for providing a packaged microchip, the method comprising: fixing one or more dies to a substrate, a die of the one or more dies comprising a circuit fabricated on a semiconductor, and the one or more dies having a substrate surface, which faces the substrate, and a thermal-interface surface on an opposite surface of the die from the substrate surface; forming a protection layer provided directly on the thermal-interface surface of the one or more dies; fixing a lid to the substrate to form a space between the protection layer and the lid through which a cooling liquid flows to cool the packaged microchip.

Aspect 19. The method of aspect 18, further comprising: fixing the one or more dies to the substrate by reflowing solder microbumps between the one or more dies and the substrate ; forming the protection layer using chemical vapor deposition to deposit diamond on the thermal-interface surface of the one or more dies; forming a molding material around side surfaces of the one or more dies; fixing the substrate to a printed circuit board by reflowing other solder microbumps between the printed circuit board and the substrate; and fixing the lid to the printed circuit board either directly or via a stiffener member that connects to the printed circuit board and the lid, wherein the substrate is a silicon interposer, and the lid comprises an inlet port through which the cooling liquid flows into the space and an outlet port through which the cooling liquid flows out of the space.

Aspect 20. The method of aspect 18 or aspect 19, wherein, in addition to being impervious to the cooling liquid, the protection layer is corrosion resistant to the cooling liquid thereby protecting the one or more dies from the cooling liquid leaking from the space to the one or more dies.

Aspect 21. The method of any of aspects 18-20, wherein the protection layer has a die surface and a heat-dissipating surface, the die surface being a surface that faces the one or more dies, and the heat-dissipating surface having a structure.

Aspect 22. The method of aspect 21, wherein the structure has been formed by etching the protection layer.

Aspect 23. The method of aspect 21 or aspect 22, wherein the structure increases thermal transfer from the protection layer to the cooling liquid by increasing a surface area over which the protection layer contacts the cooling liquid.

Aspect 24. The method of any of aspects 21-23, wherein the structure on the protection layer includes a microstructure or a nanostructure.

Aspect 25. The method of any of aspects 21-24, wherein the structure on the protection layer includes fins that have a long dimension that runs along a direction of flow of the cooling liquid.

Aspect 26. The method of any of aspects 21-25, wherein the structure on the protection layer provide one or more channels arranged such that the cooling liquid passes through the one or more channels.

Aspect 27. The method of any of aspects 18-26, wherein the protection layer is diamond.

Aspect 28. The method of aspect 27, wherein the protection layer has a thermal conductivity greater than 300 W/mK and is corrosion-resistant to the cooling liquid.

Aspect 29. The method of aspect 28, the diamond is grown directly on a heat-dissipating side of the one or more dies using chemical vapor deposition.

Aspect 30. The method of any of aspects 18-29, wherein the protection layer comprises a metal or a crystalline material.

Aspect 31. The method of any of aspects 18-30, wherein the space between the protection layer and the lid provides at least a grade 2 hermetic seal protecting the one or more dies from the cooling liquid in the space.

Aspect 32. The method of any of aspects 18-31, wherein the protection layer is provided directly on the thermal-interface surface by depositing or growing the protection layer on the thermal-interface surface using chemical vapor deposition, physical vapor deposition, pulsed laser deposition, molecular beam epitaxy, sputter deposition, epitaxial growth, or electron beam deposition.

Aspect 33. The method of any of aspects 18-32, wherein: the lid includes an inlet port through which the cooling liquid enters the space and an outlet port through which the cooling liquid exits the space, the protection layer has a die surface and a heat-dissipating surface, the die surface being a surface that faces the one or more dies, and the heat-dissipating surface having a structure, and the structure is arranged to provide laminar flow of the cooling liquid when the cooling liquid is flowing from the port to the outlet port.

Aspect 34. The method of any of aspects 18-33, wherein: the lid includes an inlet port through which the cooling liquid enters the space and an outlet port through which the cooling liquid exits the space, the protection layer has a die surface and a heat-dissipating surface, the die surface being a surface that faces the one or more dies, and the heat-dissipating surface having a structure, and the structure is arranged to provide turbulant flow of the cooling liquid when the cooling liquid is flowing from the inlet port to the outlet port.

What is claimed is:

1. A packaged microchip, comprising:
a substrate;
one or more dies comprising a circuit fabricated on a semiconductor, a die of the one or more dies having a substrate surface and a thermal-interface surface on an opposite surface of the die from the substrate surface, the die being fixed to the substrate by the substrate surface of the die;
a protection layer provided directly on the thermal-interface surface, the protection layer being impervious to a cooling liquid; and
a lid fixed to the substrate and forming a space between the protection layer and the lid that is configured to allow the cooling liquid to flow thereby cooling the packaged microchip.

2. The packaged microchip of claim 1, wherein the protection layer has a thermal conductivity greater than 300 W/mK and is corrosion-resistant to the cooling liquid.

3. The packaged microchip of claim 1, wherein the protection layer is diamond.

4. The packaged microchip of claim 3, the diamond is grown directly on a heat-dissipating side of the one or more dies using chemical vapor deposition.

5. The packaged microchip of claim 1, wherein the protection layer comprises a metal or a crystalline material.

6. The packaged microchip of claim 1, wherein:
in addition to the substrate surface and the thermal-interface surface, the one or more dies have side surfaces, and a molding is provided around the side surfaces of the one or more dies,
the substrate is a silicon interposer that is fixed to the one or more dies via solder reflow of microbumps,
the silicon interposer is connected to a printed circuit board via another solder reflow of other microbumps,
the lid is either directly fixed to the printed circuit board or indirectly fixed to the printed circuit board via one or more stiffener members, and
the lid comprises an inlet port through which the cooling liquid flows into the space and an outlet port through which the cooling liquid flows out of the space.

7. The packaged microchip of claim 1, wherein the space between the protection layer and the lid provides at least a grade 2 hermetic seal protecting the one or more dies from the cooling liquid in the space.

8. The packaged microchip of claim 1, wherein the protection layer has a die surface and a heat-dissipating surface, the die surface being a surface that faces the one or more dies, and the heat-dissipating surface having a structure.

9. The packaged microchip of claim 8, wherein the structure has been formed by etching the protection layer.

10. The packaged microchip of claim 8, wherein the structure increases thermal transfer from the protection layer to the cooling liquid by increasing a surface area over which the protection layer contacts the cooling liquid.

11. The packaged microchip of claim 8, wherein the structure on the protection layer includes a microstructure or a nanostructure.

12. The packaged microchip of claim 8, wherein the structure on the protection layer includes fins that have a long dimension that runs along a direction of flow of the cooling liquid.

13. The packaged microchip of claim 8, wherein the structure on the protection layer provide one or more channels arranged such that the cooling liquid passes through the one or more channels.

14. The packaged microchip of claim 1, wherein, in addition to being impervious to the cooling liquid, the protection layer is corrosion resistant to the cooling liquid thereby protecting the one or more dies from the cooling liquid leaking from the space to the one or more dies.

15. The packaged microchip of claim 1, wherein the protection layer is provided directly on the thermal-interface surface by depositing or growing the protection layer on the thermal-interface surface using chemical vapor deposition, physical vapor deposition, pulsed laser deposition, molecular beam epitaxy, sputter deposition, epitaxial growth, or electron beam deposition.

16. The packaged microchip of claim 1, further comprising:
an inlet port through which the cooling liquid enters the space; and
an outlet port through which the cooling liquid exits the space, wherein
the protection layer has a die surface and a heat-dissipating surface, the die surface being a surface that faces the one or more dies, and the heat-dissipating surface having a structure, and
the structure is arranged to provide laminar flow of the cooling liquid when the cooling liquid is flowing from the inlet port to the outlet port.

17. The packaged microchip of claim 1, further comprising:
an inlet port through which the cooling liquid enters the space; and
an outlet port through which the cooling liquid exits the space, wherein
the protection layer has a die surface and a heat-dissipating surface, the die surface being a surface that faces the one or more dies, and the heat-dissipating surface having a structure, and
the structure is arranged to provide turbulant flow of the cooling liquid when the cooling liquid is flowing from the port to the outlet port.

18. A method for providing a packaged microchip, the method comprising:
fixing one or more dies to a substrate, a die of the one or more dies comprising a circuit fabricated on a semiconductor, and the one or more dies having a substrate surface, which faces the substrate, and a thermal-interface surface on an opposite surface of the die from the substrate surface;
forming a protection layer provided directly on the thermal-interface surface of the one or more dies;
fixing a lid to the substrate to form a space between the protection layer and the lid through which a cooling liquid flows to cool the packaged microchip.

19. The method of claim 18, further comprising:
fixing the one or more dies to the substrate by reflowing solder microbumps between the one or more dies and the substrate ;
forming the protection layer using chemical vapor deposition to deposit diamond on the thermal-interface surface of the one or more dies;
forming a molding material around side surfaces of the one or more dies;
fixing the substrate to a printed circuit board by reflowing other solder microbumps between the printed circuit board and the substrate; and
fixing the lid to the printed circuit board either directly or via a stiffener member that connects to the printed circuit board and the lid, wherein
the substrate is a silicon interposer, and
the lid comprises an inlet port through which the cooling liquid flows into the space and an outlet port through which the cooling liquid flows out of the space.

20. The method of claim 18, wherein, in addition to being impervious to the cooling liquid, the protection layer is corrosion resistant to the cooling liquid thereby protecting the one or more dies from the cooling liquid leaking from the space to the one or more dies.
